(19) United States
(12) Patent Application Publication
(10) Pub. No.: US 2024/0145263 A1
(43) Pub. Date: May 2, 2024

(54) SUBSTRATE TREATING APPARATUS

(71) Applicant: SEMES CO., LTD., Chungcheongnam-do (KR)

(72) Inventors: Seung Hoon OH, Chungcheongnam-do (KR); Ki Bong KIM, Gyeonggi-do (KR); Jong Doo LEE, Chungcheongnam-do (KR); Young Hun LEE, Chungcheongnam-do (KR); Mi So PARK, Daejeon (KR); Jin Se PARK, Chungcheongnam-do (KR); Yong Sun KO, Gyeonggi-do (KR)

(21) Appl. No.: 18/099,856

(22) Filed: Jan. 20, 2023

(30) Foreign Application Priority Data
Oct. 27, 2022 (KR) 10-2022-0139802

(51) Int. Cl. H01L 21/67

(52) U.S. Cl. CPC H01L 21/67034

(57) ABSTRACT

According to an aspect of the present disclosure, there is provided a substrate treating apparatus comprising: a vessel part having a substrate treatment region formed therein and including a supply port through which a treating fluid is supplied to the substrate treatment region and an exhaust port through which the treating fluid is exhausted from the substrate treatment region; a fluid supply unit configured to supply the treating fluid to the substrate treatment region; an exhaust unit configured to exhaust the treating fluid from the vessel part. The exhaust unit comprises: a main line connected to the exhaust port; an extension line branched from at least one of first and second nodes of the main line and including at least one of a first orifice or a first check valve to control an exhaust speed; and an auxiliary line branched from a third node of the main line, where an orifice and a check valve are not formed. During a first process time, the treating fluid is discharged through the extension line, and the treating fluid is not discharged through the auxiliary line, and during a second process time, the treating fluid is discharged through the auxiliary line.

### CROSS-REFERENCE TO RELATED APPLICATION

This application claims priority from Korean Patent Application No. 10-2022-0139802 filed on Oct. 27, 2022 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a substrate treating apparatus.

### 2. Description of the Related Art

In order to manufacture a semiconductor device, various processes such as deposition, photography, etching, and cleaning are performed. Among them, the photographic process includes a coating process, an exposure process, and a developing process. The coating process involves coating a photosensitive liquid such as a photoresist on a substrate. The exposure process involves exposing a circuit pattern on the substrate by exposing light from a light source through a photomask on the coated photoresist film. Finally, the developing process includes selectively developing an exposed supercritical of the substrate.

The developing process includes a developer supply step, a rinsing liquid supply step, and a drying step. In the drying step, a spin chuck configured to support the substrate is rotated, and spin drying is performed to dry the developer or the rinsing liquid remaining on the substrate using a centrifugal force applied by the spin chuck to the substrate.

In recent years, with the miniaturization of a critical dimension (CD) between the pattern and the pattern formed on the substrate, a leaning phenomenon occurs which collapses or bends the pattern when the aforementioned spin drying is performed. Accordingly, a drying device using a supercritical fluid is introduced.

### SUMMARY

Meanwhile, a supercritical drying apparatus has a sealed space such that the pressure and temperature are higher normal pressure and room temperature, and treats a substrate by moving a supercritical fluid into and out of the sealed space. However, the process time has to be reduced by shortening the exhaust time of the supercritical fluid.

Aspects of the present disclosure provide a substrate treating apparatus which can reduce the process time.

The technical aspects of the present disclosure are not restricted to those set forth herein, and other unmentioned technical aspects will be clearly understood by one of ordinary skill in the art to which the present disclosure pertains by referencing the detailed description of the present disclosure given below.

### Technical Solution

According to an aspect of the present disclosure, there is provided a substrate treating apparatus comprising: a vessel part having a substrate treatment region formed therein and including a supply port through which a treating fluid is supplied to the substrate treatment region and an exhaust port through which the treating fluid is exhausted from the substrate treatment region; a fluid supply unit configured to supply the treating fluid to the substrate treatment region; and an exhaust unit configured to exhaust the treating fluid from the vessel part, wherein the exhaust unit comprises: a main line connected to the exhaust port; an extension line branched from at least one of first and second nodes of the main line and including at least one of a first orifice or a first check valve to control an exhaust speed; and an auxiliary line branched from a third node of the main line, where an orifice and a check valve are not formed, wherein, during a first process time, the treating fluid is discharged through the extension line, and the treating fluid is not discharged through the auxiliary line, and during a second process time, the treating fluid is discharged through the auxiliary line.

According to another aspect of the present disclosure, there is provided a substrate treating apparatus comprising: a vessel part having a substrate treatment region formed therein and including a supply port through which a treating fluid is supplied to the substrate treatment region and an exhaust port through which the treating fluid is exhausted from the substrate treatment region; a fluid supply unit configured to supply the treating fluid to the substrate treatment region; an exhaust unit configured to exhaust the treating fluid from the vessel part, and including a main line connected to the exhaust port, an extension line branched from at least one of the first and second nodes of the main line, and an auxiliary line branched from a third node of the main line; a first tank connected to the extension line; and a second tank physically separated from the first tank and connected to the auxiliary line.

According to another aspect of the present disclosure, there is provided a substrate treating apparatus comprising: a chamber member having an accommodation space formed therein; a control box provided adjacent to the chamber member; a vessel part provided in the accommodation space, having a substrate treatment region formed to treat a substrate whose liquid film is treated with an organic solvent, and including a supply port through which supercritical CO₂ as a supercritical fluid is supplied to the substrate treatment region and an exhaust port through which the supercritical fluid is exhausted from the substrate treatment region; a fluid supply unit configured to supply the supercritical fluid to the substrate treatment region; and an exhaust unit configured to exhaust the supercritical fluid from the vessel part, wherein the exhaust unit comprises: a main line connected to the exhaust port; a first line branched from a first node of the main line and including at least one of a first orifice or a first check valve disposed within the control box to control an exhaust speed; a second line branched from a second node of the main line and including at least one of a second orifice or a second check valve disposed within the control box; an auxiliary line branched from a third node of the main line within the chamber member, where an orifice and a check valve are not formed; a first tank to which the first line and the second line are connected; and a second tank physically separated from the first tank and connected to the auxiliary line, wherein a first valve provided in the first line and a second valve provided in the second line close a flow path with the power turned off and open the flow path with the power turned on, a third valve provided in the auxiliary line closes the flow path with the power turned on and opens the flow path with the power turned off, during a first process time, the supercritical fluid is discharged through the first line, during a second process time, the supercritical fluid is discharged through the second line, during the first and second process time, the supercritical fluid is not discharged through the auxiliary line, and during a third process time, the supercritical fluid is discharged through the auxiliary line, but the auxiliary line is opened below a critical pressure, and the supercritical fluid is exhausted at an exhaust speed faster than a maximum exhaust speed of the first and second lines.

Specific details of other embodiments are included in the detailed description and the drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating a substrate treating apparatus according to some embodiments of the present disclosure;

FIG. 2 is a view illustrating the inside of a supercritical chamber of the substrate treating apparatus according to some embodiments of the present disclosure;

FIG. 3 is a view illustrating the substrate treating apparatus according to a first embodiment of the present disclosure;

FIG. 4 is a view illustrating a state where a treating fluid is supplied through a lower supply line in the substrate treating apparatus according to a second embodiment of the present disclosure;

FIG. 5 is a view illustrating a state in which the treating fluid is supplied via an upper supply line and the treating fluid is exhausted via a first line in the substrate treating apparatus according to the second embodiment of the present disclosure;

FIG. 6 is a view illustrating a state where the treating fluid is exhausted via a second line in the substrate treating apparatus according to the second embodiment of the present disclosure;

FIG. 7 is a view illustrating a state in which the treating fluid is exhausted via an auxiliary line in the substrate treating apparatus according to the second embodiment of the present disclosure;

FIG. 8 is a view illustrating pressure change over time of the substrate treating apparatus according to some embodiments of the present disclosure;

FIG. 9 is a view illustrating opening or closing of a flow path over time of the substrate treating apparatus according to some embodiments of the present disclosure;

FIG. 10 is a view illustrating the pressure change over time of the substrate treating apparatus of a comparative embodiment;

FIG. 11 is a flowchart explaining the substrate treating method of the substrate treating apparatus according to some embodiments of the present disclosure; and

FIG. 12 is a flowchart explaining the opening of a flow path of an extension line in a substrate treating method of the substrate treating apparatus according to some embodiments of the present disclosure.

### DETAILED DESCRIPTION OF THE EMBODIMENTS

Hereinafter, embodiments of the present disclosure will be described with reference to the attached drawings. The merits and characteristics of the present disclosure and a method for achieving the merits and characteristics will become more apparent from the embodiments described in detail in conjunction with the accompanying drawings. However, the present disclosure is not limited to the disclosed embodiments, but may be implemented in various different ways. The embodiments are provided to only complete the disclosure of the present disclosure and to allow those skilled in the art to understand the category of the present disclosure. The present disclosure is defined by the category of the claims. Like numbers refer to like elements throughout the description of the figures.

The terminology used herein is for the purpose of describing particular embodiments only and is not intended to be limiting of the disclosure. In this specification, the singular also includes the plural unless specifically stated otherwise in the phrase. As used herein, “comprises” and/or “comprising” refers to the presence of one or more other components, steps, operations and/or elements. Or does not exclude additions.

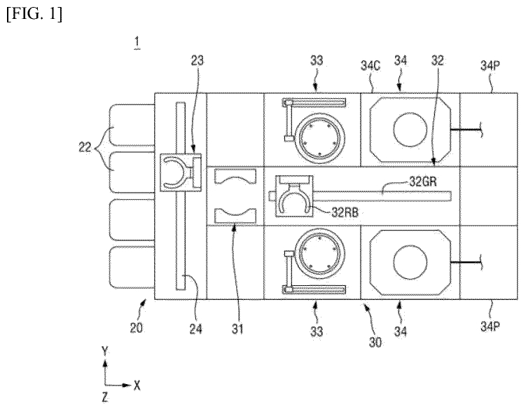

FIG. 1 is a view illustrating a substrate treating apparatus according to some embodiments of the present disclosure.

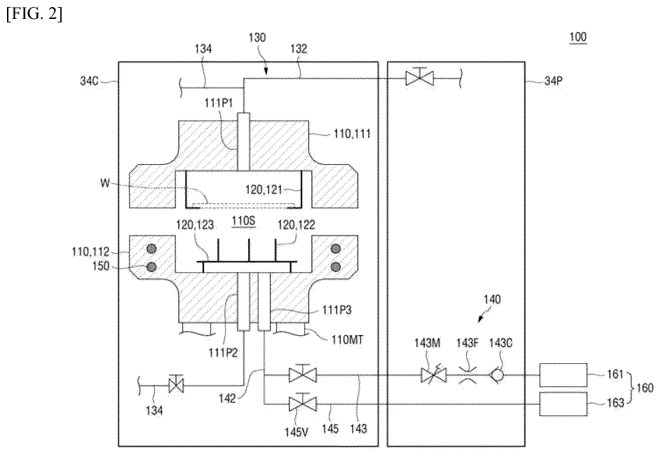

FIG. 2 is a view illustrating the inside of a supercritical chamber of the substrate treating apparatus according to some embodiments of the present disclosure First, referring to FIG. 1, the substrate treating apparatus 1 may include an index module and a treating module 30. For example, the index module 20 and the treating module 30 may be arranged in a line along an X-axis direction.

The index module 20 may transport a substrate W to the treating module 30 from a container (not shown) where the substrate W is accommodated, and may accommodate the treated substrate W in the container. For example, the index module 20 may include a load port 22 and an index robot 23. The container where the substrate W is accommodated may be placed in the load port 22. The index robot 23 can be moved along a guide rail 24 provided in the Y-axis direction.

The treating module 30 may include a buffer chamber 31, a transport chamber 32, a wet treating chamber 33, and a supercritical chamber 34.

The buffer chamber 31 may be provided between the index module 20 and the transport chamber 32. However, the present disclosure is not limited thereto. The buffer chamber 31 may store a plurality of substrates W together. The substrate W stored in the buffer chamber 31 may be carried in or out by the index robot 23 and a transport robot 32RB.

The transport chamber 32 may transport the substrate W between the wet treating chamber 33 and the supercritical chamber 34. The longitudinal direction of the transport chamber 32 may be provided in parallel with the X-axis direction. The transport robot 32RB may be provided in the transport chamber 32. The transport robot 32RB may have a hand on which the substrate W is placed. A guide rail 32GR whose longitudinal direction is provided in parallel with the X-axis direction may be provided in the transport chamber 32, and the transport robot 32RB can be moved on the guide rail 32GR.

The wet treating chamber 33 may treat a liquid film on the substrate W. For instance, the wet treating chamber 33 may perform a cleaning process on the substrate W and clean a pattern surface of the substrate W. As a treating liquid discharged from the wet treating chamber 33 is a cleaning liquid, it may include a chemical, pure water (DIW), and an organic solvent. The organic solvent may include isopropyl alcohol (IPA).

The supercritical chamber 34 may be provided adjacent to the wet treating chamber 33. The supercritical chamber 34 may treat the substrate W by supplying a supercritical fluid to the substrate W. For example, the supercritical chamber 34 may dry the substrate W by supplying the supercritical fluid to the substrate W treated in the wet treating chamber 33. In other words, the supercritical chamber 34 may dry the organic solvent remaining on the substrate W. The supercritical fluid may be, for example, supercritical CO₂.

Hereinafter, the substrate treating apparatus 100 that performs supercritical drying in the supercritical chamber 34 will be described with reference to the drawings.

Referring to FIG. 2, the substrate treating apparatus 100 according to the first embodiment may include a chamber member 34C, a control box 34P, a vessel part 110, a substrate support unit 120, a fluid supply unit 130, an exhaust unit 140, a heating member 150, and a drain tank 160.

A plurality of chamber members 34C be provided not only in the horizontal direction but also in the vertical direction so that a plurality of supercritical drying spaces are provided. However, the present disclosure is not limited thereto.

The chamber member 34C may form an accommodation space where the vessel part 110 is accommodated. In other words, the chamber member 34C may be provided to partition spaces such as the buffer chamber 31 and the wet treating chamber 33. The chamber member 34C may have an opening (not shown) through which the substrate W is moved inside or outside.

The control box 34P may be provided adjacent to the chamber member 34C. For example, the control box 34P may accommodate a storage tank (not shown) of the fluid supply unit 130 and the exhaust unit 140.

The vessel part 110 may provide a substrate treatment region 110S (which may be a supercritical treatment space) in which a drying process is performed. The vessel part 110 may have an upper body 111 provided at an upper part thereof and a lower body 112 provided at a lower part thereof, and the upper body 111 and the lower body 112 may be coupled to provide the substrate treatment region 110S.

One of the upper body 111 and the lower body 112 may be moved relative to the other body, which may be performed by a first driving part 110MT. For example, the position of the upper body 111 may be fixed, and the lower body 112 may ascend and descend by the first driving part 110MT. Herein, the first driving part 110MT may consist of, for instance, an actuator using pneumatic or hydraulic pressure, a linear motor operated by electromagnetic interaction, or a ball screw mechanism.

When the lower body 112 is spaced apart from the upper body 111, the substrate treatment region 110S is opened, and in that case, the substrate W may be carried in or out. During the process, the lower body 112 may get in close contact with the upper body 111 to seal the substrate treatment region 110S from the outside.

In addition, the vessel part 110 may include an upper supply port 111P1, a lower supply port 111P2, and an exhaust port 111P3. Herein, the upper supply port 111P1 may form a supply flow path of a treating fluid provided in the upper body 111, and the lower supply port 111P2 may form a supply flow path of the treating fluid provided in the lower body 112. The exhaust port 111P3 may form an exhaust flow path of the treating fluid provided in the lower body 112.

The substrate support unit 120 may support the substrate W in the state where the substrate W is horizontal in the substrate treatment region 110S of the vessel part 110. The substrate support unit 120 may support a treated surface of the substrate W to face upwards. The substrate support unit 120 may include a first support member 121, a second support member 122, and a plate 123.

The first support member 121 and the second support member 122 may have different regions supporting the substrate W. The first support member 121 may support an edge region of the substrate W, while the second support member 122 may support a central region of the substrate W.

For example, the first support member 121 may extend downwards from the upper body 111 but may be bent towards the substrate W. The second support member 122 may be installed on the plate 123. For example, the plate 123 may be provided as a circular plate. The plate 123 may be disposed between the lower supply port 111P2 and the first support member 121.

The plate 123 may have a diameter covering both the lower supply port 111P2 and the exhaust port 111P3. Accordingly, the flow path of the treating fluid supplied from the lower supply port 111P2 may be bypassed by the plate 123. In other words, the plate 123 can prevent the supercritical fluid supplied from the lower supply port 111P2 from being directly supplied to a non-treated surface of the substrate W.

The fluid supply unit 130 may supply the treating fluid, which is a fluid for drying, to the substrate treatment region 110S of the vessel part 110. For example, the treating fluid may be supplied to the substrate treatment region 110S in a supercritical state by a critical temperature and a critical pressure. However, the present disclosure is not limited thereto.

For example, the fluid supply unit 130 may include a storage tank (not shown) where the fluid is stored, an upper supply line 132, and a lower supply line 134. The upper supply line 132 may be connected to the upper supply port 111P1. The lower supply line 134 may be branched from the upper supply line 132 and connected to the lower supply port 111P2.

The treating fluid (which may be supercritical CO₂) stored in the storage tank may be supplied to the substrate treatment region 110S through the upper supply line 132 and the lower supply line 134. A valve (not shown) can be provided in each of the upper supply line 132 and the lower supply line 134 to adjust a flow rate of the treating fluid.

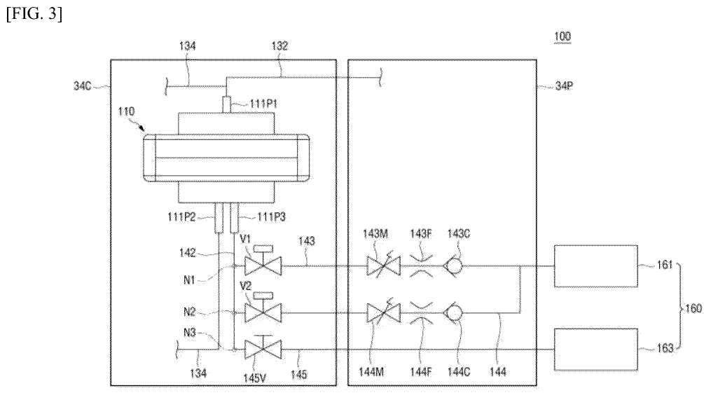

The exhaust unit 140 may include a main line 142, an extension line, an auxiliary line 145, and a pump (not shown). According to the modification of the embodiment, the extension line may include a first line 143 and a second line 144 (see FIG. 3). In other words, the extension line may be provided as a plurality of lines, and each of the first line 143 and the second line 144 may be provided as one or more lines.

Hereinafter, it will be described that the extension line of the first embodiment is provided as the first line 143.

The pump may be provided in at least one of the main line 142, the first line 143, and the auxiliary line 145 for forced exhaust. Furthermore, in the second embodiment, a pump may be provided in the second line 144.

The exhaust of the treating fluid of the exhaust unit 140 is identical or similar to that of the second embodiment. Said differently, there is a difference between the first and second embodiments in that the exhaust of the first line 143 of the first embodiment is divided into the first line 143 and the second line 144 of the second embodiment. Since the first embodiment integrates the exhaust of the first line 143 and the second line 144 of the second embodiment into one, the description overlapping with the first embodiment will be omitted in the description of the second embodiment.

The heating member 150 can heat the substrate treatment region 110S so that the substrate treatment region 110S can have or maintain the temperature required for the process. The heating member 150 may heat the supercritical fluid supplied to the substrate treatment region 110S above the critical temperature to maintain a supercritical fluid phase.

The heating member 150 may be embedded in a wall of the lower body 112 (or the upper body 111). For instance, the heating member 150 may receive power from the outside and provide the power to a heater that generates heat.

The drain tank 160 is a component through which the treating fluid (i.e., a reactant) that dried the substrate W is drained. The drain tank 160 may include a first tank 161 and a second tank 163. The drain tank 160 may store the treating fluid containing organic solvents (IPA), such as carcinogens, which are difficult to arbitrarily discharge into the atmosphere, and may form an accommodation space isolated from the outside.

The first tank 161 and the second tank 163 may be physically separated, and they are spaced apart. Each of the first tank 161 and the second tank 163 may store a supercritical fluid exhausted from the substrate treatment region 110S.

The first tank 161 may be connected to the first line 143 (which may be the first line 143 and the second line 144 in the second embodiment) and then store the supercritical fluid exhausted during the supercritical treatment of the substrate W. The second tank 163 may be connected to the auxiliary line 145 and then store the supercritical fluid exhausted in the process of completing the supercritical treatment. In this way, since the first tank 161 and the second tank 163 are separated from each other, the space shortage of the first tank 161 may be resolved in the second tank 163.

In addition, each of the first tank 161 and the second tank 163 may be provided with an exhaust manifold (not shown), and since pressure is not released during the exhaust process, different pressure may be reduced between the exhaust manifold (or the first tank 161) and an extension line 143. When an exhaust speed is slowed by a decrease in a different pressure, the exhaust time may gradually increase at the time of exhaust using the extension line 143 (see FIG. 10, exhaust continues after T4).

In the present embodiment, since the extension line 143 forming a slow vent and the auxiliary line 145 forming a fast vent are identified by the first tank 161 and the second tank 163, respectively, the exhaust speed can be prevented from decreasing depending on a decrease of the different pressure between the extension line 143 and the first tank 161, thereby performing and continuing rapid exhaust.

In other words, even if the different pressure decreases due to an increase of the exhaust amount and/or a reverse pressure occurs due to the lack of the accommodation space in the first tank 161, since the exhaust of the auxiliary line 145 is performed in the second tank 163, quality deterioration can be avoided by preventing phenomena such as re-introduction of particles due to the different pressure and/or reverse pressure during the process.

In addition, even if various emergency situations (e.g., the supercritical fluid trapped inside the vessel part 110 due to a power failure) that may occur in the substrate treating apparatus 100 occur, it can be responded to by using the auxiliary line 145. This can be achieved by providing the third valve 145V provided in the auxiliary line 145 as a valve that opens the flow path when the power is turned off, which will be described below with reference to FIG. 3.

Hereinafter, the modification of the present embodiment will be described with reference to the drawings, and a redundant description of the same components having the same function will be omitted.

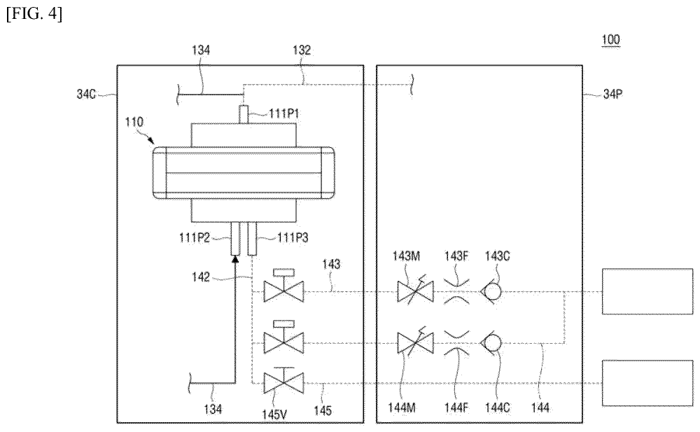

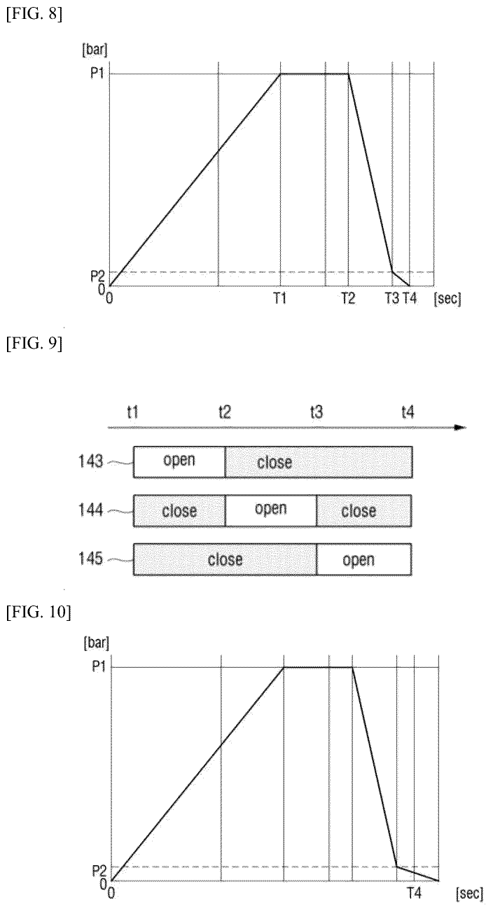

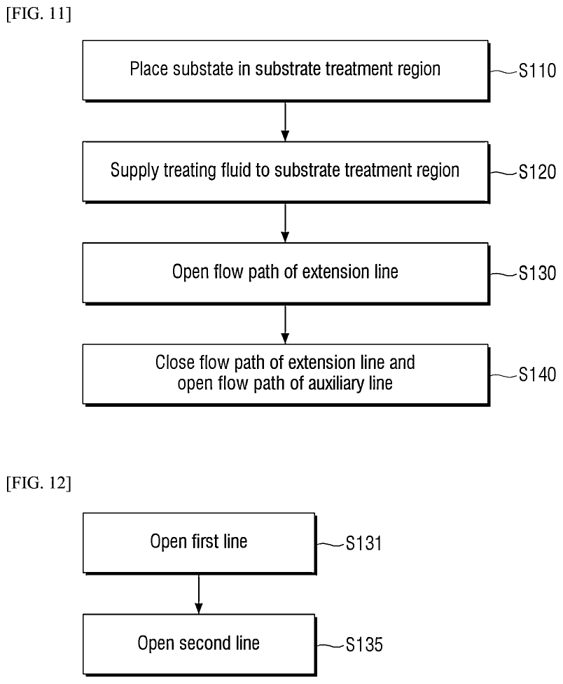

FIG. 3 is a view illustrating the substrate treating apparatus according to a first embodiment of the present disclosure. FIGS. 4 to 7 are views illustrating the flow of the treating fluid flowing in and out of the substrate treating apparatus according to the second embodiment of the present disclosure. FIG. 8 is a view illustrating pressure change over time of the substrate treating apparatus according to some embodiments of the present disclosure. FIG. 9 is a view illustrating opening or closing of a flow path over time of the substrate treating apparatus according to some embodiments of the present disclosure. FIG. 10 is a view illustrating the pressure change over time of the substrate treating apparatus of a comparative embodiment. In addition, FIGS. 11 and 12 are flowcharts illustrating a substrate treating method of the substrate treating apparatus according to some embodiments of the present disclosure.

First, in FIG. 3, the substrate treating apparatus 100 according to the second embodiment may include the chamber member 34C, the control box 34P, the vessel part 110, the substrate support unit 120, the fluid supply unit 130, the exhaust unit 140, the heating member 150, and the drain tank 160, identically or similarly to the first embodiment.

However, the extension line of the second embodiment is different from the first embodiment in that the extension line includes the first line 143 and the second line 144. In other words, the extension line of the second embodiment may be formed of a plurality of lines.

The exhaust unit 140 of the second embodiment is provided as the main line 142, the first line 143, the second line 144, and the auxiliary line 145 as follows.

The main line 142 is connected to the exhaust port 111P3 provided in the lower body 112 to exhaust the treating fluid from the substrate treatment region 110S to the outside. The main line 142 may form an upstream region where the treating fluid is exhausted, by connecting each of the first line 143, the second line 144 and the auxiliary line 145 to the main line 142.

For instance, the main line 142 may include a first node N1, a second node N2, and a third node N3. The main line 142 may form a manifold structure, but the present disclosure is not limited thereto.

The first line 143 may be branched from the first node N1 of the main line 142. The first line 143 is provided with a first metering valve 143M, a first orifice 143F, and/or a first check valve 143C in the control box 34P, and the exhaust speed of the treating fluid can be adjusted by controlling these components.

The second line 144 may be branched from the second node N2 of the main line 142. The second line 144 is provided with a second metering valve 144M, a second orifice 144F, and/or a second check valve 144C in the control box 34P, and the exhaust speed of the treating fluid can be adjusted by controlling these components.

The sizes and diameters of the first metering valve 143M, the first orifice 143F, the first check valve 143C, the second metering valve 144M, the second orifice 144F, and the second check valve 144C may be different from each other.

For example, the diameters of the first orifice 143F and the second orifice 144 may differ. This is to have a diameter to optimize the exhaust speed of the first line 143 and/or the second line 144 so as to achieve the form where the maximum exhaust speed values of the first line 143 and the second line 144 are different. However, the present disclosure is not limited thereto.

In addition, for fluid supply and interruption, a first valve V1 may be provided in the first line 143, while a second valve V2 may be provided in the second line 144. For instance, the first valve V1 and the second valve V2 may be provided as valves configured to close the flow path with the power turned off and open the flow path with the power turned on. The valve configured to open the flow path with the power turned on may have a structure that maintains a closed state with a spring force. Accordingly, such a valve has a longer lifespan than a valve (maintaining a closed state at a fluid driving pressure) that closes the flow path with the power turned on.

The auxiliary line 145 may be branched from the third node N3 of the main line 142 but may be branched from the chamber member 34C disposed in front of the control box 34P. In other words, since the auxiliary line 145 is not branched from the first line 143 or the second line 144 having the resistance flow path formed therein, it may perform exhaust without getting affected by the exhaust speed of the first line 143 and the second line 144.

Since the auxiliary line 145 does not form an orifice and a check valve having the resistance flow path formed therein, the inner diameter between the rear end of the third valve 145V and the second tank 163 may be constant. Accordingly, the auxiliary line 145 can exhaust at a speed faster than the maximum exhaust speed of the first line 143 and the second line 144. Furthermore, as described above, the auxiliary line 145 can exhaust separately from the decrease in the different pressure occurring between the first line 143 and/or the second line 144 and the first tank 161 so that the rapid exhaust can be achieved.

As described above, when the exhaust of the first line 143 or the second line 144 advances, the different pressure between the internal pressure of the substrate treatment region 110S and the first tank 161 (or an exhaust manifold) may be reduced. The reduction in the different pressure leads to a delay in the exhaust using the first line 143 or the second line 144.

However, since the present embodiment performs the exhaust using the auxiliary line 145 connected to the second tank 163, the fast vent can be performed/continued without the exhaust delay occurring in the first line 143 or the second line 144.

The auxiliary line 145 may be provided with the third valve 145V. The third valve 145V of the auxiliary line 145 may be provided as a valve configured to close the flow path with the power turned on and open the flow path the power turned off. The auxiliary line 145 may be opened during the power failure and then exhaust the treating fluid in the vessel part 110.

For another example, the third valve 145V may be provided as a valve configured to close the flow path with the power turned off and open the flow path with the power turned on, identically to similarly to the first valve V1 and/or the second valve V2. In that case, a separate line branched from a fourth node (not shown) of the main line 142 may be further provided, and the separate line may be provided with a valve configured to open the flow path with the power turned off and can exhaust the fluid from the inside of the vessel part 110 in an emergency such as the power failure.

Accordingly, the introduction and discharge (supply and exhaust) of the treating fluid may be performed by the exhaust unit 140 and the fluid supply unit 130.

Hereinafter, a substrate treating method will be described with reference to the drawings.

Referring to FIGS. 4 to 9, 11 and 12, the substrate treating apparatus 100 including the chamber member 34C, the control box 34P, the vessel part 110, the substrate support unit 120, the fluid supply unit 130, the exhaust unit 140, the heating member 150, and the drain tank 110S are provided, and the substrate W is placed in the substrate treatment region 110S (S110). Then, the treating fluid is supplied from the fluid supply unit 130 to the substrate treatment region 110S during the first process time and the second process time (S120). During the second process time and a third process time (i.e., the process time followed by the second process time), the flow path of the extension line is opened (S130), and then, during a fourth process time, the flow path of the extension line may be closed and the flow path of the auxiliary line 145 may be opened. Herein, it is noted that the time process is classified into the first, second, third, and fourth process times for convenience of explanation and understanding, and the present disclosure not limited to such terms. In what follows, this will be described in more detail.

First, the substrate treating apparatus 100 of the first and second embodiments may be provided. Hereinafter, it will be described that the substrate treating apparatus 100 of the second embodiment is provided.

Then, the substrate W may be placed in the substrate treatment region 110S (S110). To this end, since the upper body 111 and the lower body 112 are spaced apart from each other, the substrate treatment region 110S may be opened (see FIG. 2). The substrate W may be carried in using the transport robot 32RB.

Then, referring to FIGS. 4 and 8 (S120), the treating fluid may be supplied to the vessel part 110. For example, the treating fluid may be supplied to the substrate treatment region 110S through the lower supply line 134 between time 0 and time T1, i.e., the first process time. Herein, the treating fluid passing through the lower supply line 134 and the lower supply port 111P2 may be bypassed without being directly supplied to the non-treated surface of the substrate W by the plate 123.

Herein, when the treating fluid is supplied to the vessel part 110, the supplying from the lower part first is to minimize the leaning phenomenon. For instance, when the treating fluid is supplied from the upper part of the substrate W, an influence of the discharge pressure of the treating fluid supplied from the upper part of the substrate W may occur. In other words, due to the discharge pressure of the treating fluid, since the liquid film of the wet substrate W is pushed into the pattern, the leaning phenomenon may occur which collapses or bends the pattern. In order to prevent this problem, the treating fluid may be first supplied from the lower part.

When the substrate treatment region 110S is filled with the treating fluid, the pressure is maintained above a critical pressure (see FIG. 8, above a set pressure formed of P1), and a supercritical drying treatment may be performed. Herein, the supercritical drying treatment may be performed by the treating fluid passing through the upper supply port 111P1. In that case, the lower supply line 134 may be closed.

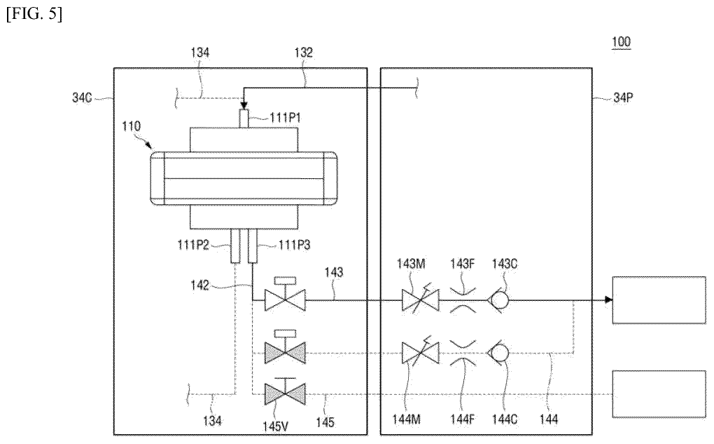

That is, referring to FIGS. 5, 8 and 9 (S130 and S131), the pressure of the substrate treatment region 110S may be maintained during the supercritical drying treatment (for the time T1 and time T2 i.e., the second process time). The pressure maintenance may be achieved by performing the exhaust simultaneously with supplying the treating fluid supplied from the upper supply port 111P1.

For example, during the supercritical drying, the treating fluid may be continuously supplied to the upper part of the substrate W via the upper supply line 132 and the upper supply port 111P1 between the time T1 and the time T2 so that the reactants in which the treating fluid and the organic solvent IPA are substituted are exhausted and a new treating fluid dries the substrate W. In that case, an exhaust operation may be performed together to maintain the internal pressure of the substrate treatment region 110S. The exhaust operation may be performed by exhausting the treating fluid (i.e., the reactant) via the exhaust port 111P3. The treating fluid passing through the exhaust port 111P3 may be exhausted through the first line 143.

In other words, in the first line 143, the flow path is opened above the critical pressure so that the substrate treatment region 110S remains supercritical in a first state where the substrate W is treated and the supercritical fluid is supplied, but the amount of the treating fluid in the same range as the amount of the treating fluid supplied from the fluid supply unit 130 can be exhausted so that the pressure is not lowered below P1 that is the pressure set between the time T1 and the time T2.

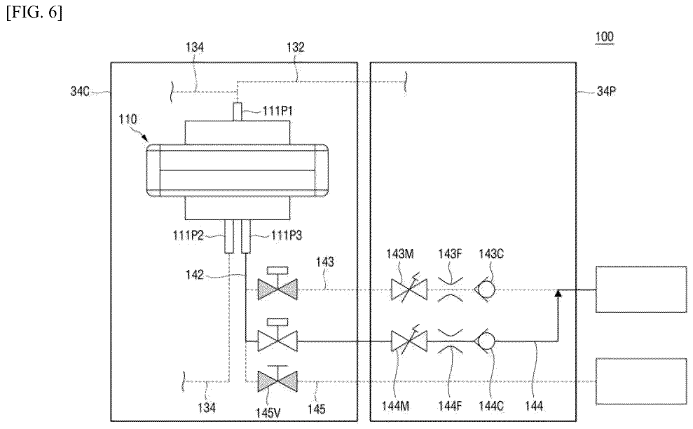

Referring to FIGS. 6, 8, and 9 (S130 and S132), while approaching the completion time of the supercritical drying treatment, before time T3, for example the supply of the treating fluid may be interrupted between the time T2 and the time T3, i.e., the third process time, and the exhaust of the treating fluid from the substrate treatment region 110S may be continued. To this end, both the upper supply line 132 and the lower supply line 134 may be closed.

In addition, the exhaust operation may be performed in the first line 143 or the second line 144. The previously performed exhaust speed of the first line 143 may be different from that of the second line 144.

Hereinafter, the exhaust operation between the time T2 and the time T3, i.e., the third process time, will be described as being performed in the second line 144. When the treating fluid is exhausted from the substrate treatment region 110S, the exhaust between the time T2 and the time T3 may can lead to exhausting the treating fluid at a first exhaust speed so that the supercritical state of the treating fluid around the substrate W is not rapidly released. Herein, the first exhaust speed at which the supercritical state is not rapidly released may be advanced at a slower vent than a second exhaust speed. This is meant to prevent the reactant remaining on the upper part of the substrate W from falling back to the substrate W by releasing the supercritical state.

After the time T3, the treating fluid may be exhausted around the upper part of the substrate W. Therefore, the rapid exhaust may be performed to shorten the process time. In that case, the pressure may be below a critical pressure P2.

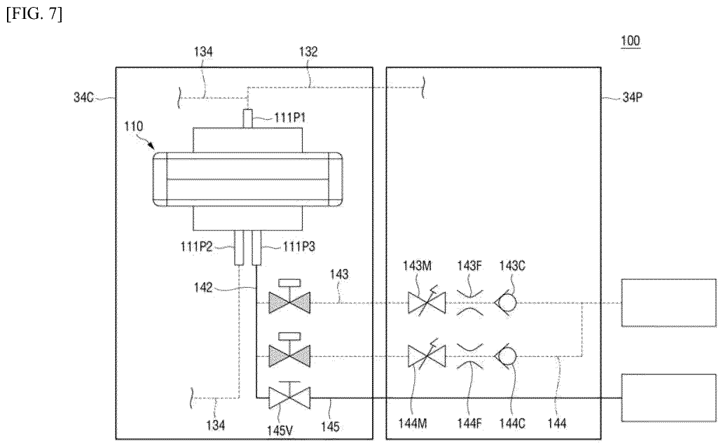

Referring to FIGS. 7, 8 and 9 (S140), the treating fluid may be exhausted from the substrate treatment region 110S through the auxiliary line 145 between the time T3 and time T4, i.e., the fourth process time.

For example, the auxiliary line 145 may be opened below the critical pressure P2 between the time T3 and the time T4 to perform the exhaust operation. The auxiliary line 145 may has an exhaust speed faster than the first exhaust speed because it does not form the metering valve, the orifice, and the check valve causing the flow path resistance, as described above. In other words, the auxiliary line 145 may exhaust the treating fluid at the second exhaust speed faster than the maximum exhaust speed of the first line 143. The second exhaust speed may be achieved at a faster vent than the first speed.

On the other hand, in the substrate treating apparatus of the comparative embodiment, when the supercritical drying is completed, the treating fluid is exhausted by the pipe forming the resistance flow path, and the different pressure with the exhaust manifold is reduced in the exhaust process, which may result in a long process time and a delay in the exhaust.

When the substrate treatment is completed as described above, the treated substrate W may be carried out. The substrate W may be carried out using the transport robot 32RB in the substrate treatment region 110S.

Although the embodiments of the present disclosure have been described above with reference to the accompanying drawings, the present disclosure is not limited to the disclosed embodiments, but may be implemented in various different ways, and the present disclosure may be embodied in many different forms without changing technical subject matters and essential features as will be understood by those skilled in the art. Therefore, embodiments set forth herein are exemplary only and not to be construed as a limitation.

### DESCRIPTION OF THE REFERENCE SYMBOLS

1, 100: substrate treating apparatus
110: vessel part
120: substrate support part

What is claimed is:

1. A substrate treating apparatus, comprising:
a vessel part having a substrate treatment region formed therein and including a supply port through which a treating fluid is supplied to the substrate treatment region and an exhaust port through which the treating fluid is exhausted from the substrate treatment region;
a fluid supply unit configured to supply the treating fluid to the substrate treatment region; and
an exhaust unit configured to exhaust the treating fluid from the vessel part,
wherein the exhaust unit comprises:
a main line connected to the exhaust port;
an extension line branched from at least one of first and second nodes of the main line and including at least one of a first orifice or a first check valve to control an exhaust speed; and
an auxiliary line branched from a third node of the main line, where an orifice and a check valve are not formed,
wherein, during a first process time, the treating fluid is discharged through the extension line, and the treating fluid is not discharged through the auxiliary line, and
during a second process time, the treating fluid is discharged through the auxiliary line.

2. The substrate treating apparatus of claim 1, wherein during the second process time, the treating fluid is not discharged through the extension line.

3. The substrate treating apparatus of claim 1, wherein the extension line is installed in a chamber member provided with the vessel part, and a control box disposed adjacent to the chamber member, and
the first orifice or the first check valve is installed in the control box.

4. The substrate treating apparatus of claim 3, wherein the auxiliary line is installed in the chamber member and the control box, and
the auxiliary line in the chamber member is provided with a valve configured to close a flow path with the power turned on and open the flow path with the power turned off.

5. The substrate treating apparatus of claim 3, wherein the first node, the second node, and the third node are formed in the chamber member.

6. The substrate treating apparatus of claim 3, wherein the extension line comprises:
a first line branched from the first node, including the first orifice or the first check valve to adjust an exhaust speed, where a flow path is opened during a first sub-process time of the first process time; and
a second line branched from the second node, including at least one of a second orifice and a second check valve to adjust the exhaust speed, where a flow path is opened during a second sub-process time of the first process time.

7. The substrate treating apparatus of claim 6, wherein the second orifice or the second check valve is installed in the control box.

8. The substrate treating apparatus of claim 6, wherein the first line exhausts the amount of the treating fluid in the same range as the amount of the treating fluid supplied from the fluid supply unit so that the internal pressure of the substrate treatment region is maintained,
the second line exhausts the treating fluid from the substrate treatment region in a state where the supply of the treating fluid supplied from the fluid supply unit is interrupted, wherein the treating fluid is exhausted at a first exhaust speed, and
the auxiliary line is opened below a critical pressure, and exhausts the treating fluid at a second exhaust speed faster than the first exhaust speed and faster than the maximum exhaust speed of the extension line.

9. The substrate treating apparatus of claim 1, wherein the second process time is followed by the first process time.

10. The substrate treating apparatus of claim 1, wherein the extension line is connected to a first tank; and
the auxiliary line is connected to a second tank physically separated from the first tank.

11. The substrate treating apparatus of claim 1, wherein the in the extension line is provided with a valve configured to close the flow path with the power turned off and to open the flow path with the power turned on.

12. The substrate treating apparatus of claim 1, wherein the treating fluid is provided as supercritical CO₂, and
the substrate is provided as a substrate whose liquid film is treated with an organic solvent, and supercritical drying is performed in the substrate treatment region.

13. A substrate treating apparatus, comprising:
a vessel part having a substrate treatment region formed therein and including a supply port through which a treating fluid is supplied to the substrate treatment region and an exhaust port through which the treating fluid is exhausted from the substrate treatment region;
a fluid supply unit configured to supply the treating fluid to the substrate treatment region;
an exhaust unit configured to exhaust the treating fluid from the vessel part, and including a main line connected to the exhaust port, an extension line branched from at least one of the first and second nodes of the main line, and an auxiliary line branched from a third node of the main line;
a first tank connected to the extension line; and
a second tank physically separated from the first tank and connected to the auxiliary line.

14. The substrate treating apparatus of claim 13, wherein the extension line includes a first line configured to discharge the treating fluid during a first process time and a second line configured to discharge the treating fluid during a second process time, and
the auxiliary line discharges the treating fluid during a third process time.

15. The substrate treating apparatus of claim 13, wherein the extension line includes at least one of an orifice or a check valve to adjust an exhaust speed, and
in the auxiliary line, the orifice and the check valve are not formed.

16. The substrate treating apparatus of claim 13, wherein the treating fluid is provided as supercritical CO₂, and
the substrate is provided as a substrate whose liquid film is treated with an organic solvent, and supercritical drying is performed in the substrate treatment region.

17. A substrate treating apparatus, comprising:
a chamber member having an accommodation space formed therein;
a control box provided adjacent to the chamber member;
a vessel part provided in the accommodation space, having a substrate treatment region formed to treat a substrate whose liquid film is treated with an organic solvent, and including a supply port through which supercritical CO₂ as a supercritical fluid is supplied to the substrate treatment region and an exhaust port through which the supercritical fluid is exhausted from the substrate treatment region;
a fluid supply unit configured to supply the supercritical fluid to the substrate treatment region; and
an exhaust unit configured to exhaust the supercritical fluid from the vessel part,
wherein the exhaust unit comprises:
a main line connected to the exhaust port;
a first line branched from a first node of the main line and including at least one of a first orifice or a first check valve disposed within the control box to control an exhaust speed;
a second line branched from a second node of the main line and including at least one of a second orifice or a second check valve disposed within the control box;
an auxiliary line branched from a third node of the main line within the chamber member, where an orifice and a check valve are not formed;
a first tank to which the first line and the second line are connected; and
a second tank physically separated from the first tank and connected to the auxiliary line,
wherein a first valve provided in the first line and a second valve provided in the second line close a flow path with the power turned off and open the flow path with the power turned on,
a third valve provided in the auxiliary line closes the flow path with the power turned on and opens the flow path with the power turned off,
during a first process time, the supercritical fluid is discharged through the first line,
during a second process time, the supercritical fluid is discharged through the second line,
during the first and second process time, the supercritical fluid is not discharged through the auxiliary line, and
during a third process time, the supercritical fluid is discharged through the auxiliary line, but the auxiliary line is opened below a critical pressure, and the supercritical fluid is exhausted at an exhaust speed faster than a maximum exhaust speed of the first and second lines.
